(19) United States
(12) Patent Application Publication
(10) Pub. No.: US 2025/0358928 A1
(43) Pub. Date: Nov. 20, 2025

(54) DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xinpeng WANG, Beijing (CN); Yunhan XIAO, Beijing (CN); Rendong LI, Beijing (CN); Hengzhen LIANG, Beijing (CN); Lianbin LIU, Beijing (CN); Dong WANG, Beijing (CN); Hao HUANG, Beijing (CN); Chenghong YANG, Beijing (CN); Fan LI, Beijing (CN); Qianlin PU, Beijing (CN); Jianli YAO, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/854,562

(22) PCT Filed: Jan. 15, 2024
(86) PCT No.: PCT/CN2024/072364

§ 371 Date: Oct. 7, 2024

(30) Foreign Application Priority Data
Feb. 28, 2023 (CN) 202310215320.8

(51) Int. Cl. H05K 1/02

(52) U.S. Cl. CPC H05K 1/028; H05K 2201/10128

(57) ABSTRACT

Provided is a display device, including a display panel and a FPC. The FPC includes a fixed portion and a bendable portion. The bendable portion has a first side edge extending along a length direction of the bendable portion. The FPC includes a plurality of layers, in which the first trace layer has a first inward contraction amount relative to the substrate layer in a first region of the first side edge, the second trace layer has a second inward contraction amount relative to the substrate layer in the first region of the first side edge, and the first electromagnetic shielding layer has a third inward contraction amount relative to the substrate layer in the first region of the first side edge. At least two of the first inward contraction amount, the second inward contraction amount, and the third inward contraction amount are not equal.

### CROSS-REFERENCE TO RELATED APPLICATIONS

This application is a U.S. national stage of international application No. PCT/CN2024/072364, filed on Jan. 15, 2024, which claims priority to Chinese Patent Application No. 202310215320.8, filed on Feb. 28, 2023, and entitled “DISPLAY DEVICE”, the disclosures of each are incorporated herein by reference in their entireties.

### TECHNICAL FIELD

Embodiments of the present disclosure relate to the field of display technologies, and in particular, to a display device.

### BACKGROUND

Display devices are widely used in people's daily life, such as mobile phones, displays, or tablet computers.

### SUMMARY

The present disclosure provides a display device. The technical solutions are as follows.

A display device is provided. The display device includes an FPC and a display panel. The FPC is electrically connected to the display panel, and the FPC includes a fixed portion and a bendable portion. The fixed portion is connected to a back surface of the display panel, the bendable portion is connected to the fixed portion, and the bendable portion has a first side edge extending along a length direction of the bendable portion. The FPC includes a first protective layer, a first trace layer, a substrate layer, a second trace layer, a second protective layer, and a first electromagnetic shielding layer that are stacked in sequence. The first trace layer has a first inward contraction amount relative to the substrate layer in a first region of the first side edge, the second trace layer has a second inward contraction amount relative to the substrate layer in the first region of the first side edge, and the first electromagnetic shielding layer has a third inward contraction amount relative to the substrate layer in the first region of the first side edge. At least two of the first inward contraction amount, the second inward contraction amount, and the third inward contraction amount are not equal.

In some embodiments, the first inward contraction amount is greater than or less than the second inward contraction amount, and the third inward contraction amount is greater than at least one of the first inward contraction amount and the second inward contraction amount.

In some embodiments, one of the first inward contraction amount and the second inward contraction amount is greater than 0 mm and is less than or equal to 0.3 mm, and another one the first inward contraction amount and the second inward contraction amount ranges from 0.4 mm to 1.0 mm; and the third inward contraction amount ranges from 0.45 mm to 1 mm.

In some embodiments, the bendable portion further has a second side edge extending along the length direction of the bendable portion, and the second side edge is opposite to the first side edge. The first trace layer has a fourth inward contraction amount relative to the substrate layer in a second region of the second side edge, the second trace layer has a fifth inward contraction amount relative to the substrate layer in the second region of the second side edge, and the first electromagnetic shielding layer has a sixth inward contraction amount relative to the substrate layer in the second region of the second side edge. At least two of the fourth inward contraction amount, the fifth inward contraction amount, and the sixth inward contraction amount are not equal.

In some embodiments, the fourth inward contraction amount is greater than or less than the fifth inward contraction amount, and the sixth inward contraction amount is greater than at least one of the fourth inward contraction amount and the fifth inward contraction amount.

In some embodiments, the first inward contraction amount is equal to or not equal to the fourth inward contraction amount, the second inward contraction amount is equal to or not equal to the fifth inward contraction amount, and the third inward contraction amount is equal to or not equal to the sixth inward contraction amount.

In some embodiments, the FPC further includes a second electromagnetic shielding layer disposed on a side, away from the second protective layer, of the first protective layer. The second electromagnetic shielding layer has a seventh inward contraction amount relative to the substrate layer in the first region of the first side edge, and the second electromagnetic shielding layer has an eighth inward contraction amount relative to the substrate layer in the second region of the second side edge.

In some embodiments, the seventh inward contraction amount is greater than or less than the third inward contraction amount, and the seventh inward contraction amount is greater than at least one of the first inward contraction amount and the second inward contraction amount; the eighth inward contraction amount is greater than or less than the sixth inward contraction amount, and the eighth inward contraction amount is greater than at least one of the fourth inward contraction amount and the fifth inward contraction amount.

In some embodiments, a length of the first region of the first side edge is equal to a length of the second region of the second side edge; or a length of the first region of the first side edge is not equal to a length of the second region of the second side edge.

In some embodiments, in a direction perpendicular to the length direction of the bendable portion, an orthographic projection of the first region of the first side edge on the second side edge is at least partially overlapped with the second region of the second side edge, or an orthographic projection of the first region of the first side edge on the second side edge is not overlapped with the second region of the second side edge.

In some embodiments, a size of the first region of the first side edge and a size of the second region of the second side edge in the length direction of the bendable portion are greater than 5 mm and are less than or equal to a length of the bendable portion.

In some embodiments, a length of the bendable portion of the FPC is greater than 5 mm and is less than or equal to 90 mm.

In some embodiments, the fixed portion of the FPC includes at least two trace layers stacked in sequence, wherein any adjacent two trace layers of the at least two trace layers are respectively in a same layer as the first trace layer and the second trace layer.

In some embodiments, a side, away from the display panel, of the fixed portion includes a first device region and a second device region; and the FPC further includes a touch chip and a stiffener. The touch chip is disposed in the first device region, and the stiffener is disposed between the fixed portion and the back surface of the display panel. An orthographic projection of the touch chip on the back surface of the display panel is within an orthographic projection of the stiffener on the back surface of the display panel, and an orthographic projection of the second device region on the back surface of the display panel is outside the orthographic projection of the stiffener on the back surface of the display panel.

In some embodiments, the FPC further includes a non-conductive adhesive layer disposed on a side, close to the display panel, of the fixed portion. The orthographic projection of the stiffener on the back surface of the display panel is not overlapped with an orthographic projection of the non-conductive adhesive layer on the back surface of the display panel, and an orthographic projection of the second device region on the substrate layer is at least partially overlapped with an orthographic projection of the non-conductive adhesive layer on the substrate layer.

In some embodiments, the display device further includes a ground plane disposed on the back surface of the display panel, wherein the ground plane is provided with a groove, and the stiffener is disposed in the groove.

The embodiments of the present disclosure further provide an FPC. The FPC includes a bendable portion, wherein the bendable portion has a first side edge extending along a length direction of the bendable portion. The flexible printed circuit board includes a first protective layer, a first trace layer, a substrate layer, a second trace layer, a second protective layer, and a first electromagnetic shielding layer that are stacked in sequence. The first trace layer has a first inward contraction amount relative to the substrate layer in a first region of the first side edge, the second trace layer has a second inward contraction amount relative to the substrate layer in the first region of the first side edge, and the first electromagnetic shielding layer has a third inward contraction amount relative to the substrate layer in the first region of the first side edge. At least two of the first inward contraction amount, the second inward contraction amount, and the third inward contraction amount are not equal.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following descriptions show merely some embodiments of the present disclosure, and persons of ordinary skill in the art may still derive other drawings from these accompanying drawings without creative effort.

FIG. 1 is a schematic structural diagram of a display device according to some embodiments of the present disclosure;

FIG. 2 is a schematic diagram of a side of an FPC away from a display panel according to some embodiments of the present disclosure;

FIG. 3 is a structural sectional view of an FPC according to some embodiments of the present disclosure;

FIG. 4 is a structural sectional view of another FPC according to some embodiments of the present disclosure;

FIG. 5 is a schematic diagram of a side of an FPC close to a display panel according to some embodiments of the present disclosure;

FIG. 6 is a schematic diagram of an arrangement of a stiffener according to some embodiments of the present disclosure;

FIG. 7 is a schematic diagram of another arrangement of a stiffener according to some embodiments of the present disclosure; and

FIG. 8 is a schematic diagram of a side of a display panel close to an FPC according to some embodiments of the present disclosure.

### DETAILED DESCRIPTION

To make the objects, technical solutions, and advantages of the present disclosure clearer, the embodiments of the present disclosure are further described in detail hereinafter with reference to the accompanying drawings.

The terms in the section of the detailed description of the present disclosure are merely used for the purpose of explaining the embodiments of the present disclosure, and are not intended to limit the present disclosure. Unless otherwise defined, the technical terms or scientific terms used in the embodiments of the present disclosure shall have ordinary meanings as understood by a person skilled in the art to which the present disclosure belongs. The terms “first,” “second,” “third,” and the like used in the description and claims of the present disclosure do not indicate any order, quantity, or importance, but rather are merely used to distinguish different components. Similarly, the term “an,” or “a,” is not intended to limit the number of components but means at least one. The term “include” or “comprise” and similar terms are intended to mean that the element or object before “include” or “comprise” covers the elements or objects or equivalents listed behind “include” or “comprise,” without excluding other elements or objects.

A display device generally includes a display panel and a flexible printed circuit board (FPC). The display panel is electrically connected to the FPC. The FPC includes a fixed portion connected to a back surface of the display panel and a bendable portion connected to the fixed portion.

In actual applications, the bendable portion of the FPC is likely to be bent and distorted. Consequently, stress concentration likely occurs on the edges of the FPC, resulting in the risk of edge tearing.

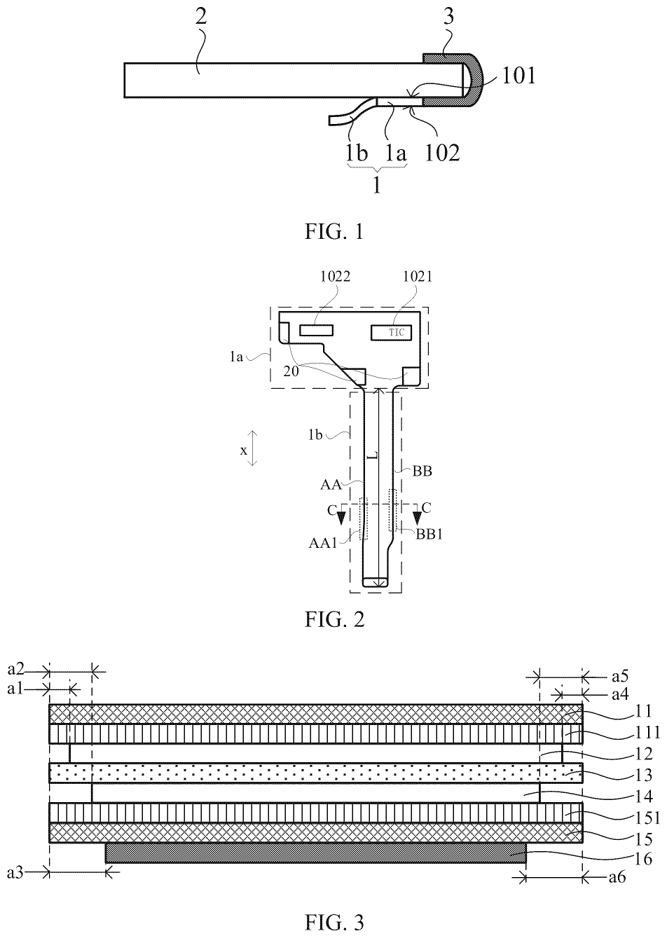

FIG. 1 is a schematic structural diagram of a display device according to some embodiments of the present disclosure. As shown in FIG. 1, the display device includes an FPC 1 and a display panel 2. The FPC 1 is electrically connected to the display panel 2. The FPC 1 includes a fixed portion 1a and a bendable portion 1b, the fixed portion 1a is connected to a back surface of the display panel 2, and the bendable portion 1b is connected to the fixed portion 1a.

In some embodiments, the display device further includes an encapsulated circuit board 3, and the FPC 1 is electrically connected to the display panel 2 through the encapsulated circuit board 3. One end of the encapsulated circuit board 3 is disposed on a display surface of the display panel 2 and is connected to the display panel 2, and the opposite end of the encapsulated circuit board 3 is disposed on the back surface of the display panel 2. The fixed portion 1a is disposed on the back surface of the display panel 2 and is connected to one end of the encapsulated circuit board 3. Here, the back surface of the display panel 2 is a side surface opposite to the display surface of the display panel 2. The display surface is a side surface for displaying an image, which is also referred to as a light-exiting surface.

In some embodiments, the encapsulated circuit board 3 is a chip on glass (COG) circuit board, a chip on film (COF) circuit board, or a chip on pi (COP) circuit board. In some embodiments, in a flexible display device adopting the COP circuit board, the display panel and the COP circuit board are manufactured as an integral structure. Here, COG, COF, and COP refer to three circuit encapsulation ways, and generally, one of the three ways is used to achieve bonding to the display panel and bonding to the FPC in a display device. The following describes the structure of the encapsulated circuit board by taking the structure of the COF circuit board as an example. The COF circuit board (i.e., the encapsulated circuit board 3) includes a thin film circuit board body, i.e., a COF film. A drive chip is provided in the thin film circuit board body. A mainboard controls the drive chip on the encapsulated circuit board 3 by means of the FPC 1, thereby controlling the display panel 2 to display images.

In some embodiments, the display panel 2 is an organic light-emitting diode (OLED) display panel. In some other embodiments, the display panel is a liquid crystal display panel, a micro light-emitting diode display panel, or other types of display panels.

FIG. 2 is a schematic diagram of a side 102 of an FPC away from a display panel according to some embodiments of the present disclosure. As shown in FIG. 2, the bendable portion 1b has a first side edge AA extending along a length direction x of the bendable portion 1b. The bendable portion 1b further has a second side edge BB extending along the length direction x of the bendable portion 1b, the second side edge BB is opposite to the first side edge AA. It should be noted that FIG. 2 is illustrated by taking an example in which the left side edge is the first side edge AA and the right side edge is the second side edge BB. In other possible implementations, the right side edge is the first side edge AA, and the left side edge is the second side edge BB.

In some embodiments, a length L of the bendable portion 1b of the FPC 1 is greater than 5 mm and is less than or equal to 90 mm.

Different products have different middle frames, and the length of the bendable portion of the FPC is designed according to demands so as to ensure that the FPC matches the edge of the middle frame.

In the embodiments of the present disclosure, in order to be connected to the mainboard, one end, away from the fixed portion 1a, of the bendable portion 1b is provided with a connector for connecting to the mainboard.

In the related art, the bendable portion 1b of the FPC 1 includes a first protective layer, a first trace layer, a substrate layer, a second trace layer, a second protective layer, and a first electromagnetic shielding layer that are stacked in sequence. Edges of the first protective layer, the substrate layer, the electromagnetic shielding layer, and the second protective layer are flush with each other, edges of the first trace layer and the second trace layer are flush with each other, and the orthographic projection of the first trace layer on the substrate layer is within the substrate layer.

In actual applications, in the case that the bendable portion of the FPC is bent and distorted, stress concentration likely occurs at the edge of the FPC having the plurality of layers with flush edges, resulting in the risk of edge tearing.

FIG. 3 is a structural sectional view of an FPC according to some embodiments of the present disclosure, and FIG. 3 is a schematic diagram of a sectional structure along line CC in FIG. 2. In some embodiments, the FPC 1 includes a first protective layer 11, a first trace layer 12, a substrate layer 13, a second trace layer 14, a second protective layer 15, and a first electromagnetic shielding layer 16 that are stacked in sequence.

The first trace layer 12 has a first inward contraction amount a1 relative to the substrate layer 13 in a first region of the first side edge AA, the second trace layer 14 has a second inward contraction amount a2 relative to the substrate layer 13 in the first region, and the first electromagnetic shielding layer 16 has a third inward contraction amount a3 relative to the substrate layer 13 in the first region. At least two of the first inward contraction amount a1, the second inward contraction amount a2, and the third inward contraction amount a3 are not equal. The first trace layer 12 has a fourth inward contraction amount a4 relative to the substrate layer 13 in a second region of the second side edge BB, the second trace layer 14 has a fifth inward contraction amount a5 relative to the substrate layer 13 in the second region, and the first electromagnetic shielding layer 16 has a sixth inward contraction amount a6 relative to the substrate layer 13 in the second region. At least two of the fourth inward contraction amount a4, the fifth inward contraction amount a5, and the sixth inward contraction amount a6 are not equal.

In the embodiments of the present disclosure, the structure that the first trace layer 12, the second trace layer 14, and the first electromagnetic shielding layer 16 have inward contraction amounts in the first region of the first side edge AA or the second region of the second side edge BB is referred to as an inward contraction design. In some embodiments, the bendable portion 1b of the FPC 1 is designed to be contracted inwardly throughout the first side edge AA, and the first region refers to the entire first side edge AA. In some other embodiments, the bendable portion 1b of the FPC 1 is designed to be contracted inwardly in a partial region of the first side edge AA. In some embodiments, the first region is region AA1 shown in FIG. 2. Similarly, in some embodiments, the bendable portion 1b of the FPC 1 is designed to be contracted inwardly throughout the second side edge BB, and the second region is the entire second side edge BB. Alternatively, in some embodiments, the bendable portion 1b of the FPC 1 is designed to be contracted inwardly in a partial region of the second side edge BB. In some embodiments, the second region is region BB1 shown in FIG. 2.

In some embodiments, the dimensions of the first region and the second region in the length direction x of the bendable portion 1b are greater than 5 mm and are less than or equal to the length L, which allows the portion of the bendable portion 1b that is designed to be contracted inwardly to have sufficient flexibility.

In the embodiments of the present disclosure, the first inward contraction amount a1, the second inward contraction amount a2, and the third inward contraction amount a3 are respectively the minimum distances from the edges, close to the first side edge AA, of the orthographic projections of the first trace layer 12, the second trace layer 14, and the first electromagnetic shielding layer 16 on the substrate layer 13 to the edge, close to the first side edge AA, of the substrate layer 13. The fourth inward contraction amount a4, the fifth inward contraction amount a5, and the sixth inward contraction amount a6 are respectively the minimum distances from the edges, close to the second side edge BB, of the orthographic projections of the first trace layer 12, the second trace layer 14, and the first electromagnetic shielding layer 16 on the substrate layer 13 to the edge, close to the second side edge BB, of the substrate layer 13.

In the embodiments of the present disclosure, each of the first trace layer 12, the second trace layer 14, and the first electromagnetic shielding layer 16 have inward contraction amounts relative to other layers in the first region of the first side edge AA and the second region of the second side edge BB, and at least two of the three inward contraction amounts of the first trace layer 12, the second trace layer 14, and the first electromagnetic shielding layer 16 at the same side edge are not equal. That is, the plurality of layers of the FPC are not flush with each other at the first region and the second region, which makes the FPC less prone to stress concentration at the edges upon being bent and distorted, thereby reducing the risk of tearing. In addition, because each of the first trace layer 12, the second trace layer 14, and the first electromagnetic shielding layer 16 have inward contraction amounts relative to other layers at both the first region of the first side edge AA and the second region of the second side edge BB, the outer edge of the first region of the first side edge AA and the outer edge of the second region of the second side edge BB are only provided with the first protective layer 11 and the second protective layer 15 instead of the first trace layer 12, the second trace layer 14, or the first electromagnetic shielding layer 16. Therefore, during assembling, stresses at the edges are effectively transferred through the deformation of the first protective layer 11 and the second protective layer 15, thereby preventing the internal trace region from compression and deformation.

In some embodiments, only two of the first inward contraction amount a1, the second inward contraction amount a2, and the third inward contraction amount a3 are equal. In some embodiments, the first inward contraction amount a1 is equal to the second inward contraction amount a2, and the first inward contraction amount a1 is not equal to the third inward contraction amount a3. In some other embodiments, the first inward contraction amount a1, the second inward contraction amount a2, and the third inward contraction amount a3 are not equal to each other, which further reduces the risk of edge tearing of the FPC upon the FPC being distorted and deformed.

In some embodiments, only two of the fourth inward contraction amount a4, the fifth inward contraction amount a5, and the sixth inward contraction amount a6 are equal. In some embodiments, the fourth inward contraction amount a4 is equal to the fifth inward contraction amount a5, and the fourth inward contraction amount a4 is not equal to the sixth inward contraction amount a6. In some other embodiments, the fourth inward contraction amount a4, the fifth inward contraction amount a5, and the sixth inward contraction amount a6 are not equal to each other, which further reduces the risk of edge tearing of the FPC upon the FPC being distorted and deformed.

In some embodiments, the third inward contraction amount a3 is between the first inward contraction amount a1 and the second inward contraction amount a2. In some other embodiments, the third inward contraction amount a3 is the largest among the first inward contraction amount a1, the second inward contraction amount a2, and the third inward contraction amount a3, which reduces the stress on the side, close to the first side edge AA, of the first electromagnetic shielding layer as much as possible upon the FPC being distorted and deformed.

In some embodiments, the sixth inward contraction amount a6 is between the fourth inward contraction amount a4 and the fifth inward contraction amount a5. In some other embodiments, the sixth inward contraction amount a6 is the largest among the fourth inward contraction amount a4, the fifth inward contraction amount a5, and the sixth inward contraction amount a6, which reduces the stress on the side, close to the second side edge BB, of the first electromagnetic shielding layer as much as possible upon the FPC being distorted and deformed.

In some embodiments, as shown in FIG. 3, the first inward contraction amount a1 is less than the second inward contraction amount a2, and the third inward contraction amount a3 is greater than the first inward contraction amount a1 and the second inward contraction amount a2; and the fourth inward contraction amount a4 is less than the fifth inward contraction amount a5, and the sixth inward contraction amount a6 is greater than the fourth inward contraction amount a4 and the fifth inward contraction amount a5.

In some other embodiments, the first inward contraction amount a1 is greater than the second inward contraction amount a2, and the third inward contraction amount a3 is greater than the first inward contraction amount a1 or the second inward contraction amount a2; and the fourth inward contraction amount a4 is greater than the fifth inward contraction amount a5, and the sixth inward contraction amount a6 is greater than the fourth inward contraction amount a4 or the fifth inward contraction amount a5.

The inward contraction design ensures that the first trace layer 12 and the second trace layer 14 are insulated, and at the same time alleviates, through the uneven edges achieved by the inward contractions of the first trace layer 12 and the second trace layer 14, the edge tearing due to stress concentration caused by bending and distortion. In addition, the first electromagnetic shielding layer is inwardly contracted with an inward contraction amount not being smallest, such that the second protective layer 15 at the first side edge AA and the second side edge BB plays a sufficient protective role, i.e., the stresses on edges are effectively transferred by deformation of the second protective layer 15, thereby preventing the internal trace region from compression and deformation.

In some embodiments, one of the first inward contraction amount a1 and the second inward contraction amount a2 is greater than 0 mm and is less than or equal to 0.3 mm, and another one of the first inward contraction amount a1 and the second inward contraction amount a2 ranges from 0.4 mm to 1.0 mm. The third inward contraction amount a3 ranges from 0.45 mm to 1.0 mm. One of the fourth inward contraction amount a4 and the fifth inward contraction amount a5 is greater than 0 mm and is less than or equal to 0.3 mm, and another one of the fourth inward contraction amount a4 and the fifth inward contraction amount a5 ranges from 0.4 mm to 1.0 mm. The sixth inward contraction amount a6 ranges from 0.45 mm to 1.0 mm.

The inward contraction amounts of the first trace layer 12, the second trace layer 14, and the electromagnetic shielding layer 16 are designed according to different application scenarios. In some embodiments, as shown in FIG. 3, the first inward contraction amount a1 is equal to the fourth inward contraction amount a4, the second inward contraction amount a2 is equal to the fifth inward contraction amount a5, and the third inward contraction amount a3 is equal to the sixth inward contraction amount a6. In some other embodiments, at least one of the groups of the first inward contraction amount a1 and the fourth inward contraction amount a4, the second inward contraction amount a2 and the fifth inward contraction amount a5, and the third inward contraction amount a3 and the sixth inward contraction amount a6 is not equal to each other.

In some embodiments, the lengths of the first region and the second region are greater than 5 mm. As mentioned above, because the length L of the bendable portion is greater than 0 mm and less than or equal to 90 mm, the length of the first region is less than or equal to 90 mm, and the length of the second region is less than or equal to 90 mm. In some embodiments, the length of the first region is equal to the length of the second region, or the length of the first region is not equal to the length of the second region.

The position of the first region AA1 of the first side edge AA is not limited in the present disclosure. In some embodiments, the first region AA1 of the first side edge AA is located on a side away from the fixed portion 1a as shown in FIG. 2, or located on a side close to the fixed portion 1a. Similarly, the second region BB1 of the second side edge BB is located on a side away from the fixed portion 1a as shown in FIG. 2, or located on a side close to the fixed portion 1a.

Referring to FIG. 2 again, in a direction perpendicular to the length direction x of the bendable portion 1b, the projection of the first region AA1 of the first side edge AA on the second side edge BB is at least partially overlapped with the second region BB1 of the second side edge BB, i.e., the first region AA1 and the second region BB1 are opposite to each other or partially staggered with each other in the length direction x of the bendable portion 1b. In some other embodiments, in the direction perpendicular to the length direction x of the bendable portion 1b, the projection of the first region AA1 of the first side edge AA on the second side edge BB is not overlapped with the second region BB1 of the second side edge BB, i.e. the first region AA1 and the second region BB1 are completely staggered with each other in the length direction x of the bendable portion 1b.

Because different products have different models, the middle frames of different products are also different, and the bendable portions 1b are possible to be bent for different lengths at different positions. Therefore, the positions and lengths of the first region and the second region are designed according to different demands, to ensure that the FPC adapts to the edge of the middle frame, thereby reducing the extrusion force.

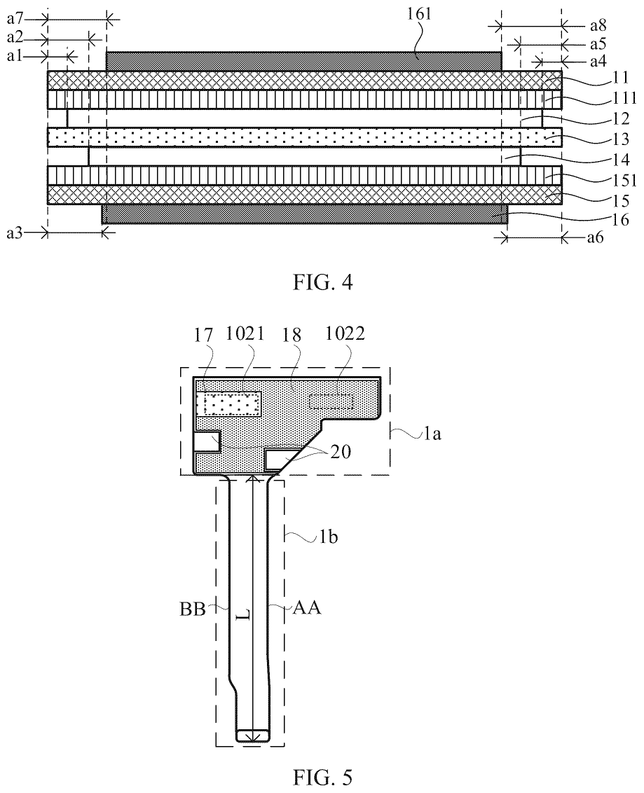

FIG. 4 is a structural sectional view of another FPC according to some embodiments of the present disclosure. In some embodiments, as shown in FIG. 4, the FPC 1 further includes a second electromagnetic shielding layer 161, wherein the second electromagnetic shielding layer 161 is disposed on the side, away from the second protective layer 15, of the first protective layer 11.

The second electromagnetic shielding layer 161 has a seventh inward contraction amount a7 relative to the substrate layer 13 in the first region, and the second electromagnetic shielding layer 161 has an eighth inward contraction amount a8 relative to the substrate layer 13 in the second region. The electromagnetic shielding layer is disposed at different positions depending on the whole machine's electromagnetic shielding condition and the radio frequency protection condition.

For the relationships of the first inward contraction amount a1, the second inward contraction amount a2, and the seventh inward contraction amount a7 and corresponding effects thereof, reference is made to the relationships of the first inward contraction amount a1, the second inward contraction amount a2, and the third inward contraction amount a3 and corresponding effects described above. For the relationships of the fourth inward contraction amount a4, the fifth inward contraction amount a5, and the eighth inward contraction amount a8 and corresponding effects thereof, reference is made to the relationships of the fourth inward contraction amount a4, the fifth inward contraction amount a5, and the sixth inward contraction amount a6 and corresponding effects described above.

In some embodiments, the seventh inward contraction amount a7 is greater than or less than the third inward contraction amount a3, and the eighth inward contraction amount a8 is greater than or less than the sixth inward contraction amount a6. In this way, the edges of the FPC are made uneven as much as possible, thereby further reducing the risk of edge tearing of the FPC upon the FPC being distorted and deformed.

In some embodiments, as shown in FIG. 4, the seventh inward contraction amount a7 is greater than the third inward contraction amount a3, and the seventh inward contraction amount a7 is greater than the first inward contraction amount a1 and the second inward contraction amount a2. The eighth inward contraction amount a8 is greater than the sixth inward contraction amount a6, and the eighth inward contraction amount a8 is greater than the fourth inward contraction amount a4 and the fifth inward contraction amount a5.

It is to be noted that in the implementation shown in FIG. 3, each of the first trace layer 12, the second trace layer 14, and the first electromagnetic shielding layer 16 has inward contraction amounts at both the first region of the first side edge AA and the second region of the second side edge BB. In other possible implementations, the first trace layer 12, the second trace layer 14, and the first electromagnetic shielding layer 16 have inward contraction amounts only at the first region of the first side edge AA. In the implementation shown in FIG. 4, the first trace layer 12, the second trace layer 14, the first electromagnetic shielding layer 16, and the second electromagnetic shielding layer 161 have inward contraction amounts at both the first region of the first side edge AA and the second region of the second side edge BB. In other possible implementations, the first trace layer 12, the second trace layer 14, the first electromagnetic shielding layer 16, and the second electromagnetic shielding layer 161 have inward contraction amounts only at the first region of the first side edge AA.

In some embodiments, both the fixed portion 1a and the bendable portion 1b of the FPC 1 include two trace layers, i.e., the first trace layer 12 and the second trace layer 14.

In some other embodiments, the bendable portion 1b of the FPC 1 includes two trace layers, i.e., the first trace layer 12 and the second trace layer 14, but the fixed portion 1a includes more than two trace layers to facilitate the routing.

In the case that the fixed portion 1a includes two trace layers, the two trace layers in the fixed portion 1a are respectively formed in the same layers as the first trace layer 12 and the second trace layer 14 in the bendable portion 1b.

In the case that the fixed portion 1a includes at least three trace layers, any two adjacent trace layers in the fixed portion 1a are respectively disposed in the same layers as the first trace layer and the second trace layer, and the trace layers disposed in the same layer are formed integrally (i.e., acquired by patterning one metal layer.)

In some embodiments, the fixed portion 1a of the FPC 1 includes four trace layers stacked sequentially, which are respectively a third trace layer, a fourth trace layer, a fifth trace layer, and a sixth trace layer in the direction close to the display panel 2.

In some embodiments, the third trace layer and the fourth trace layer are respectively disposed in the same layers as the first trace layer and the second trace layer; or the fourth trace layer and the fifth trace layer are respectively disposed in the same layers as the first trace layer and the second trace layer; or the fifth trace layer and the sixth trace layer are respectively disposed in the same layers as the first trace layer and the second trace layer, and so on.

In some embodiments, the thickness of the first protective layer 11 and the thickness of the second protective layer 15 range from 10 μm to 15.0 μm, such as 12.5 μm. The thickness of the first trace layer 12 and the thickness of the second trace layer 14 range from 10 μm to 20 μm, such as 15 μm. The thickness of the substrate layer 13 ranges from 20 μm to 30 μm, such as 25 μm. The thickness of the first electromagnetic shielding layer 16 ranges from 10 μm to 15 μm, such as 12 μm. The thickness herein refers to the size of the structural layer in the direction perpendicular to the display panel 2.

In some embodiments, the substrate layer 13 is made of polyimide (PI). The PI material has good bending performance, which can ensure the overall bending performance of the FPC.

In some embodiments, the first trace layer 12 and the second trace layer 14 are made of copper, such as rolled copper, electrolytic copper, or the like.

In some embodiments, the first protective layer 11 and the second protective layer 15 are made of PI, which can protect the FPC 1.

In some embodiments, the FPC 1 further includes a first adhesive layer 111 and a second adhesive layer 151. The first adhesive layer 111 is disposed between the first protective layer 11 and the first trace layer 12, and the second adhesive layer 151 is disposed between the second protective layer 15 and the second trace layer 14. The first protective layer 11 is connected to the first trace layer 12 via the first adhesive layer 111, and the second protective layer 15 is connected to the second trace layer 14 via the second adhesive layer 151.

In some embodiments, the thickness of the first adhesive layer 111 and the thickness of the second adhesive layer 151 range from 10 μm to 20 μm. In some embodiments, the thickness of the first adhesive layer 111 and the thickness of the second adhesive layer 151 range from 12.5 μm to 17.5 μm, such as 15 μm.

In some embodiments, the first adhesive layer 111 and the second adhesive layer 151 are made of an acrylic hot melt adhesive, a polyurethane adhesive, an epoxy resin adhesive, or the like.

In some embodiments, the display panel 2 has a touch function, and the display panel 2 includes a touch structure.

In some embodiments, the touch function of the display panel 2 is achieved by a flexible multi-layer on cell (FMLOC) module. The FMLOC module is a touch panel with a touch structure being manufactured on the outside of a thin film encapsulation layer of the display panel. The FMLOC integrates a display structure and the touch structure together, having the advantages of thinness, lightness, foldability, and the like, and meeting the product demand of flexible folding, narrow bezel, and the like.

In the design of the FMLOC module, the TIC is integrated into the FPC. In some embodiments, referring to FIG. 2, the side 102, away from the display panel 2, of the fixed portion 1a includes a first device region 1021 and a second device region 1022, wherein the first device region 1021 and the second device region 1022 are spaced apart from each other. In some embodiments, the first device region 1021 and the second device region 1022 are spaced apart from each other in the direction perpendicular to the length direction of the FPC 1. Both the first device region 1021 and the second device region 1022 are configured to holding various electronic components. In some embodiments, the fixed portion 1a of the FPC 1 includes a touch integrated circuit (TIC) and other electronic components. The TIC and the other electronic devices are disposed in the first device region 1021, wherein the other electronic components include a capacitor, a resistor, or the like. The TIC is electrically connected to the touch structure in the display panel 2 through at least one of the first trace layer 12 or the second trace layer 14 so as to transmit touch signals. The second device region 1022 is provided with electron components such as a capacitor, a resistor, or the like.

In the design of the FMLOC module, insufficient reinforcement easily occurs at the TIC on the FPC, resulting in pseudo-soldering and poor touch functions.

Therefore, in the related art, a large-area stiffener is provided on the side, close to the display panel 2, of the fixed portion 1a to provide reinforcement for the TIC. However, the large-area stiffener covers not only the TIC but also test races such as signal output lines inside the FPC. Upon the environment reliability test, the stiffener blocks the discharge of water vapor, and the water vapor penetrates into the traces, resulting in short circuits, impedance abnormalities, and the like caused by corrosion between adjacent traces. Here, covering means that the orthographic projection of the corresponding component or region on the back surface of the display panel 2 is within the orthographic projection of the stiffener 17 on the back surface of the display panel 2. In order to reinforce the TIC and solve the above problems, the present disclosure provides two ways of arranging the stiffener.

FIG. 5 is a schematic diagram of a side 101, close to a display panel, of an FPC according to some embodiments of the present disclosure. As shown in FIG. 5, the FPC 1 further includes a stiffener 17, and the stiffener 17 is disposed on the side 101, close to the display panel 2, of the FPC 1. The orthographic projection of the first device region 1021 on the stiffener 17 is within the stiffener 17, the orthographic projection of the TIC on the stiffener 17 is within the stiffener 17, and the orthographic projection of the second device region 1022 on the stiffener 17 is outside the stiffener 17. The stiffener increases the strength of the region covered by the stiffener, facilitating the soldering of the electronic components in the covered region to the FPC.

FIG. 6 is a schematic diagram of an arrangement of a stiffener according to some embodiments of the present disclosure, and FIG. 6 shows the positional relationship between the stiffener 17 and the fixed portion 1a in FIG. 5. As shown in FIG. 6, the stiffener 17 covers the first device region 1021, but does not cover the second device region 1022. That is, the orthographic projection of the first device region 1021 on the back surface of the display panel 2 is within the orthographic projection of the stiffener 17 on the back surface of the display panel 2, but the orthographic projection of the second device region 1022 on the back surface of the display panel 2 is outside the orthographic projection of the stiffener 17 on the back surface of the display panel 2.S

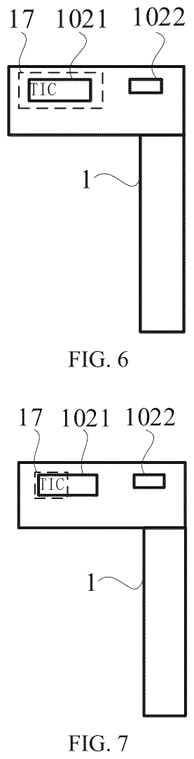

FIG. 7 is a schematic diagram of another arrangement of a stiffener according to some embodiments of the present disclosure. As shown in FIG. 7, the stiffener 17 covers a portion of the first device region 1021, and the stiffener 17 covers the TIC. That is, the orthographic projection of the TIC on the back surface of the display panel 2 is within the orthographic projection of the stiffener 17 on the back surface of the display panel 2, but an orthographic projection of a portion of the first device region 1021 on the back surface of the display panel 2 is outside the orthographic projection of the stiffener 17 on the back surface of the display panel 2. In addition, the orthographic projection of the second device region 1022 on the back surface of the display panel 2 is also outside the orthographic projection of the stiffener 17 on the back surface of the display panel 2.

The TIC is generally rectangular. In some embodiments, the shape of the stiffener 17 is the same as or different from the shape of the TIC. In some embodiments, the stiffener 17 is rectangular, circular, elliptic, hexagonal, or the like.

The following is illustrated by taking an example in which the stiffener 17 is rectangular. In the case that the stiffener 17 is rectangular, the four side edges of the stiffener are parallel to the four side edges of the TIC in one-to-one correspondence.

In the case that the orthographic projection of the TIC on the back surface of the display panel 2 is within the orthographic projection of the stiffener 17 on the back surface of the display panel 2, but the orthographic projection of a portion of the first device region 1021 on the back surface of the display panel 2 is outside of the orthographic projection of the stiffener 17 on the back surface of the display panel 2, the distance between a side edge of the orthographic projection of the TIC on the stiffener 17 and a side edge, corresponding to the side edge of the orthographic projection of the TIC, of the stiffener 17 ranges from 0.5 mm to 1 mm.

In some embodiments, in the case that the stiffener 17 covers the first device region 1021, but does not cover the second device region 1022, the distance between a side edge of the orthographic projection of the TIC on the stiffener 17 and a side edge, corresponding to the side edge of the orthographic projection of the TIC, of the stiffener 17 ranges 1 mm to 4.5 mm.

In some embodiments, the stiffener 17 is made of a steel sheet, such that the stiffener 17 is capable of providing good support for the covered region.

In some embodiments, referring to FIG. 5 again, the FPC 1 further includes a non-conductive adhesive 18, wherein the non-conductive adhesive 18 is disposed on the side 101, close to the display panel 2, of the FPC 1 and disposed on the fixed portion 1a. The orthographic projection of the stiffener 17 on the substrate layer 13 is not overlapped with the orthographic projection of the non-conductive adhesive 18 on the substrate layer 13, and the orthographic projection of the second device region 1022 on the substrate layer 13 is at least partially overlapped with the orthographic projection of the non-conductive adhesive 18 on the substrate layer 13. The non-conductive adhesive provides adhesive force to facilitate fixing the FPC to the display panel, and at the same time, the non-conductive adhesive supplements the segment difference (i.e., the gap between the display panel and the FPC) to make the FPC be fixed more firmly.

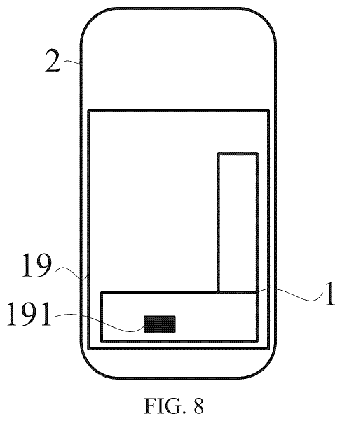

FIG. 8 is a schematic diagram of a side, close to an FPC, of a display panel according to some embodiments of the present disclosure. In some embodiments, as shown in FIG. 8, the display device further includes a ground plane 19 disposed on the back surface of the display panel 2, the ground plane 19 has a groove 191, and the stiffener 17 is disposed in the groove 191. Because the stiffener does not need to be grounded, the groove 191 is formed at a position, corresponding to the stiffener 17, of the ground plane 19, and the stiffener 17 is placed in the groove 191, thereby further reducing the thickness of the display device and saving space.

In some embodiments, the ground plane 19 covers a large area of the back surface of the display panel 2. The shape of the ground plane 19 is not limited herein, which is rectangular, trapezoidal, or the like. The ground plane 19 serves for not only conducting electricity to the ground but also dissipating heat.

In some embodiments, the ground plane includes a super clean foam (SCF) composite film, which is also referred to as a heat dissipation film.

In some embodiments, the display device further includes an adhesive tape (not shown in drawings). The adhesive tape is disposed on the side, away from the display panel 2, of the FPC 1, and the adhesive tape is adhered to at least a portion of the FPC 1, at least a portion of the encapsulated circuit board 3, and at least a portion of the back surface of the display panel 2. That is, the adhesive tape adheres to the FPC 1, the encapsulated circuit board 3, and the back surface of the display panel 2 at the same time, thereby fixing the FPC 1 and the encapsulated circuit board 3 to the back surface of the display panel 2. At least some of the electronic components (such as the drive chip) are disposed between the adhesive tape and the back surface of the display panel 2.

In some embodiments, referring to FIG. 2 and FIG. 5 again, both sides of the FPC 1 include a conductive region 20. The side, away from the display panel, of the FPC 1 shown in FIG. 2 includes a plurality of conductive regions 20, the plurality of conductive regions 20 are spaced apart from each other at the edges of the fixed portion 1a, and the conductive regions 20 are connected to the conductive layer in the adhesive tape so as to be grounded. The side, close to the display panel, of the FPC 1 shown in FIG. 5 includes a plurality of conductive regions 20, the plurality of conductive regions 20 are spaced apart from each other at the edges of the fixed portion 1a, and the plurality of conductive regions 20 are connected to the ground plane so as to be grounded.

The conductive regions 20 are achieved by exposing part of the trace layers in the FPC 1. In the case that the trace layers are made of copper, the conductive regions 20 are referred to as copper leakage regions.

It is to be noted that, in some other embodiments, only one side of the FPC 1 includes the conductive region 20.

The embodiments of the present disclosure further provide an FPC. One end of the FPC is connected to a first electronic component such as a mainboard, and a second end of the FPC is connected to a second electronic component such as a display panel.

The FPC at least includes a bendable portion, wherein the bendable portion has a first side edge extending in a length direction of the bendable portion. The FPC includes a first protective layer, a first trace layer, a substrate layer, a second trace layer, a second protective layer, and a first electromagnetic shielding layer that are stacked in sequence. The first trace layer has a first inward contraction amount relative to the substrate layer in a first region of the first side edge, the second trace layer has a second inward contraction amount relative to the substrate layer in the first region of the first side edge, and the first electromagnetic shielding layer has a third inward contraction amount relative to the substrate layer in the first region of the first side edge. At least two of the first inward contraction amount, the second inward contraction amount, and the third inward contraction amount are not equal.

For the other structures of the bendable portion, please refer to the details in the above embodiments, which are not repeated herein.

In some embodiments, the FPC further includes a fixed portion, wherein the fixed portion is configured to be fixedly connected to the first electronic component or the second electronic component. For the details of the fixed portion, please refer to the details in the above embodiments, which are not repeated herein.

In summary, the technical solutions in the present disclosure at least achieve the following beneficial effects.

The first trace layer, the second trace layer, and the first electromagnetic shielding layer are designed to be inwardly contracted relative to other layers in the first region of the first side edge, to achieve corresponding inward contraction amounts, wherein the inward contraction amounts of at least two layers of the three layers are different. In this way, the plurality of layers of the FPC are not flush with each other in the first region of the first side edge, thereby reducing the stress concentration at the edges of the FPC in the case of the FPC being bent, reducing the risk of edge tearing, and improving the non-deformability of the edges of the FPC.

Additionally, because the first electromagnetic shielding layer is designed to be inwardly contracted, the outermost layer in the first region of the first side edge is the first protective layer. In this way, during the whole device assembling, the larger stress that likely exists at the edges of the FPC is transferred by the deformation of the first protective layer, thereby preventing the first trace layer and the second trace layer from deformation caused by compression as much as possible.

Described above are merely optional embodiments of the present disclosure, and are not intended to limit the present disclosure. Any modifications, equivalent substitutions, improvements, and the like within the concept and principles of the present disclosure are all within the protection scope of the present disclosure.

1. A display device, comprising: a flexible printed circuit board and a display panel, the flexible printed circuit board being electrically connected to the display panel; wherein
the flexible printed circuit board comprises a fixed portion and a bendable portion, wherein the fixed portion is connected to a back surface of the display panel, the bendable portion is connected to the fixed portion, and the bendable portion has a first side edge extending along a length direction of the bendable portion;
the flexible printed circuit board comprises a first protective layer, a first trace layer, a substrate layer, a second trace layer, a second protective layer, and a first electromagnetic shielding layer that are stacked in sequence;
wherein the first trace layer has a first inward contraction amount relative to the substrate layer in a first region of the first side edge, the second trace layer has a second inward contraction amount relative to the substrate layer in the first region of the first side edge, and the first electromagnetic shielding layer has a third inward contraction amount relative to the substrate layer in the first region of the first side edge,
wherein at least two of the first inward contraction amount, the second inward contraction amount, and the third inward contraction amount are not equal.

2. The display device according to claim 1, wherein the first inward contraction amount is greater than or less than the second inward contraction amount, and the third inward contraction amount is greater than at least one of the first inward contraction amount and the second inward contraction amount.

3. The display device according to claim 2, one of the first inward contraction amount and the second inward contraction amount is greater than 0 mm and is less than or equal to 0.3 mm, and another one of the first inward contraction amount and the second inward contraction amount ranges from 0.4 mm to 1.0 mm; and the third inward contraction amount ranges from 0.45 mm to 1 mm.

4. The display device according to claim 1, wherein the bendable portion further has a second side edge extending along the length direction of the bendable portion, the second side edge being opposite to the first side edge;
wherein the first trace layer has a fourth inward contraction amount relative to the substrate layer in a second region of the second side edge, the second trace layer has a fifth inward contraction amount relative to the substrate layer in the second region of the second side edge, and the first electromagnetic shielding layer has a sixth inward contraction amount relative to the substrate layer in the second region of the second side edge,
wherein at least two of the fourth inward contraction amount, the fifth inward contraction amount, and the sixth inward contraction amount are not equal.

5. The display device according to claim 4, wherein the fourth inward contraction amount is greater than or less than the fifth inward contraction amount, and the sixth inward contraction amount is greater than at least one of the fourth inward contraction amount and the fifth inward contraction amount.

6. The display device according to claim 4, wherein the first inward contraction amount is equal to or not equal to the fourth inward contraction amount, the second inward contraction amount is equal to or not equal to the fifth inward contraction amount, and the third inward contraction amount is equal to or not equal to the sixth inward contraction amount.

7. The display device according to claim 4, wherein the flexible printed circuit board further comprises a second electromagnetic shielding layer disposed on a side, away from the second protective layer, of the first protective layer;
wherein the second electromagnetic shielding layer has a seventh inward contraction amount relative to the substrate layer in the first region of the first side edge, and the second electromagnetic shielding layer has an eighth inward contraction amount relative to the substrate layer in the second region of the second side edge.

8. The display device according to claim 7, wherein
the seventh inward contraction amount is greater than or less than the third inward contraction amount, and the seventh inward contraction amount is greater than at least one of the first inward contraction amount and the second inward contraction amount; and
the eighth inward contraction amount is greater than or less than the sixth inward contraction amount, and the eighth inward contraction amount is greater than at least one of the fourth inward contraction amount and the fifth inward contraction amount.

9. The display device according to claim 4, wherein a length of the first region of the first side edge is equal to a length of the second region of the second side edge.

10. The display device according to claim 9, wherein in a direction perpendicular to the length direction of the bendable portion, an orthographic projection of the first region of the first side edge on the second side edge is at least partially overlapped with the second region of the second side edge.

11. The display device according to claim 4, wherein a size of the first region of the first side edge and a size of the second region of the second side edge in the length direction of the bendable portion are greater than 5 mm and are less than or equal to a length of the bendable portion.

12. The display device according to claim 1, wherein a length of the bendable portion of the flexible printed circuit board is greater than 5 mm and is less than or equal to 90 mm.

13. The display device according to claim 1, wherein the fixed portion of the flexible printed circuit board comprises at least two trace layers stacked in sequence, wherein any adjacent two trace layers of the at least two trace layers are respectively in a same layer as the first trace layer and the second trace layer.

14. The display device according to claim 1, wherein
a side, away from the display panel, of the fixed portion comprises a first device region and a second device region; and
the flexible printed circuit board further comprises a touch chip and a stiffener, wherein the touch chip is disposed in the first device region, and the stiffener is disposed between the fixed portion and the back surface of the display panel;
wherein an orthographic projection of the touch chip on the back surface of the display panel is within an orthographic projection of the stiffener on the back surface of the display panel; and
an orthographic projection of the second device region on the back surface of the display panel is outside the orthographic projection of the stiffener on the back surface of the display panel.

15. The display device according to claim 14, wherein the flexible printed circuit board further comprises anon-conductive adhesive layer disposed on a side, close to the display panel, of the fixed portion; wherein
the orthographic projection of the stiffener on the back surface of the display panel is not overlapped with an orthographic projection of the non-conductive adhesive layer on the back surface of the display panel, and an orthographic projection of the second device region on the substrate layer is at least partially overlapped with an orthographic projection of the non-conductive adhesive layer on the substrate layer.

16. The display device according to claim 14, further comprising: a ground plane disposed on the back surface of the display panel; wherein
the ground plane is provided with a groove, and the stiffener is disposed in the groove.

17. The display device according to claim 4, wherein a length of the first region of the first side edge is not equal to a length of the second region of the second side edge.

18. The display device according to claim 9, wherein in a direction perpendicular to the length direction of the bendable portion, an orthographic projection of the first region of the first side edge on the second side edge is not overlapped with the second region of the second side edge.
